(19) United States
(12) Patent Application Publication
(10) Pub. No.: US 2017/0330726 A1
(43) Pub. Date: Nov. 16, 2017

(54) Fluorinated compositions for ion source performance improvements in nitrogen ion implantation

(71) Applicant: Entegris, Inc., Billerica, MA (US)

(72) Inventors: Barry Lewis Chambers, Midlothian, VA (US); Biing-Tsair Tien, Taoyuan (TW); Joseph D. Sweeney, New Milford, CT (US); Ying Tang, Brookfield, CT (US); Oleg Byl, Southbury, CT (US); Steven E. Bishop, Corrales, NM (US); Sharad N. Yedave, Danbury, CT (US)

(21) Appl. No.: 15/593,486

(22) Filed: May 12, 2017

Related U.S. Application Data
(60) Provisional application No. 62/336,550, filed on May 13, 2016.

(51) Int. Cl. H01J 37/317; C09D 5/24; C09D 1/00; H01J 37/32; H01L 21/67; H01L 21/265

(52) U.S. Cl. CPC H01J 37/3171; H01L 21/67213; H01L 21/265; C09D 1/00; H01J 37/3244; C09D 5/24; H01J 2237/006

(57) ABSTRACT

Compositions, methods, and apparatus are described for carrying out nitrogen ion implantation, which avoid the incidence of severe glitching when the nitrogen ion implantation is followed by another ion implantation operation susceptible to glitching, e.g., implantation of arsenic and/or phosphorus ionic species. The nitrogen ion implantation operation is advantageously conducted with a nitrogen ion implantation composition introduced to or formed in the ion source chamber of the ion implantation system, wherein the nitrogen ion implantation composition includes nitrogen (N₂) dopant gas and a glitching-suppressing gas including one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, e.g., hydrogen-containing gas including one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

### FIELD

The present disclosure generally relates to nitrogen ion implantation. More specifically, the present disclosure relates in various aspects to fluorinated compositions for ion source performance improvement in nitrogen ion implantation, to methods of improvement of ion source performance utilizing such fluorinated compositions, and to gas supply apparatus and kits for use in nitrogen ion implant systems.

### DESCRIPTION OF THE RELATED ART

Ion implantation is a widely used process in the manufacture of microelectronic and semiconductor products, being employed to accurately introduce controlled amounts of dopant impurities into substrates such as semiconductor wafers.

In ion implantation systems employed in such applications, an ion source typically is employed to ionize a desired dopant element gas, and the ions are extracted from the source in the form of an ion beam of desired energy. Various types of ion sources are used in ion implantation systems, including the Freeman and Bernas types that employ thermoelectrodes and are powered by an electric arc, microwave types using a magnetron, indirectly heated cathode (IHC) sources, and RF plasma sources, all of which typically operate in a vacuum. Dopants used in ion implantation systems are of widely varying types, and include arsenic, phosphorus, boron, oxygen, nitrogen, tellurium, carbon, and selenium, among others. Ion implantation tools may be used on an ongoing basis for implantation of a wide variety of dopant species, with the tool being operated successively to implant different dopant species, with corresponding change of operating conditions and chemistries.

In any system, the ion source generates ions by introducing electrons into a vacuum arc chamber (hereinafter “chamber”) filled with the dopant gas (commonly referred to as the “feedstock gas”). Collisions of the electrons with atoms and molecules in the dopant gas result in the creation of ionized plasma consisting of positive and negative dopant ions. The extraction electrode with a negative or positive bias will respectively allow the positive or negative ions to pass through the aperture as a collimated ion beam, which is accelerated towards the target material to form a region of desired conductivity.

Frequency and duration of preventive maintenance (PM) is one performance factor of an ion implantation tool. As a general objective, the tool PM frequency and duration should be decreased. The parts of the ion implanter tool that require the most maintenance include the ion source, the extraction electrodes and high voltage insulators, and the pumps and vacuum lines of vacuum systems associated with the tool. Additionally, the filament of the ion source is replaced on a regular basis.

Ideally, feedstock molecules dosed into an arc chamber would be ionized and fragmented without substantial interaction with the arc chamber itself or any other components of the ion implanter. In reality, feedstock gas ionization and fragmentation can results in such undesirable effects as arc chamber components etching or sputtering, deposition on arc chamber surfaces, redistribution of arc chamber wall material, etc. These effects contribute to ion beam instability, and may eventually cause premature failure of the ion source. Residues of feedstock gases and their ionization products, when deposited on the high voltage components of the ion implanter tool, such as the source insulator or the surfaces of the extraction electrodes, can also cause energetic high voltage sparking. Such sparks are another contributor to beam instability, and the energy released by these sparks can damage sensitive electronic components, leading to increased equipment failures and poor mean time between failures (MTBF).

Electrical shorts resulting from excessive deposition of solids on insulating surfaces are known as “glitching” and are highly adverse to the achievement of efficient ion implantation in the ion implant system.

Regardless of the specific type of dopant that is used in an ion implantation operation, there are common objectives of ensuring that the feedstock gases are efficiently processed, that the implantation of ion species is carried out in an effective and economic manner, and that the implanter apparatus is operated so that maintenance requirements are minimized and mean time before failure of system components is maximized so that implant tool productivity is as high as possible.

A particular glitching problem encountered in the manufacture of integrated circuitry and other microelectronic products is associated with nitrogen ion implantation. When an ion implant tool utilized for implantation of nitrogen (N⁺) is thereafter switched to operation for implantation of arsenic (As+) or phosphorus (P+), the tool is prone to severe glitching. The mechanism of such glitching is not fully elucidated, but may involve deposition of conductive tungsten nitrides (WNₓ) onto ion source insulators.

Prior efforts to address and minimize such severe glitching related to nitrogen ion implantation followed by either arsenic or phosphorus ion implantation have been unsatisfactory. For example, it has been determined that conducting an intermediate short duration (e.g., 5 minutes in length) step of processing, i.e., ionizing, a boron feedstock gas between initial nitrogen ion implantation and subsequent arsenic or phosphorus ion implantation in the ion implanter tool can attenuate the glitching behavior, but this requires resetting of the tool operating conditions and a disruption of the otherwise applicable processing sequence for the tool.

It would therefore be highly advantageous to prevent the severe glitching of ion implant tools that is experienced when such tools are switched from nitrogen ion implantation to other ion implantation operations susceptible to glitching, e.g., such as arsenic ion implantation or phosphorus ion implantation, by a preventive approach that is effective, cost-efficient, and avoids the necessity of disruptions of scheduled sequences of ion implantation operations in order to suppress such adverse glitching behavior of the tool.

### SUMMARY

The present disclosure relates to compositions, methods, and apparatus for carrying out nitrogen ion implantation, which avoids the incidence of severe glitching when the nitrogen ion implantation is followed by another ion implantation operation susceptible to glitching, such as implantation of arsenic or phosphorus ionic species.

In various aspects, the invention relates to a nitrogen ion implantation composition comprising nitrogen dopant gas (N₂) and a glitching suppressing gas comprising a source of fluorine and/or oxygen. Without wishing to be bound by theory, it is thought that fluorine and/or oxygen can intercept the reaction of nitrogen with the internals of ion sources, for example to form nitrides, which can mitigate the formation of deposits associated with glitching.

In one aspect, the disclosure relates to a nitrogen ion implantation composition for combating glitching in an ion implantation system when nitrogen ion implantation is followed by another ion implantation operation susceptible to glitching, the nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas.

In another aspect, the disclosure relates to a nitrogen ion implantation composition for combating glitching in an ion implantation system when nitrogen ion implantation is followed by arsenic ion implantation and/or phosphorus ion implantation, the nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas.

In various aspects, the invention relates to gas supply packages and kits for delivering, to an ion implantation system, nitrogen dopant gas (N₂) and a glitching suppressing gas comprising a source of fluorine and/or oxygen.

In yet another aspect, the disclosure relates to a gas supply package for supplying a nitrogen ion implantation composition to an ion implantation system, in which the gas supply package comprises a gas storage and dispensing vessel containing the nitrogen ion implantation composition as variously described herein.

In a further aspect, the disclosure relates to a gas supply kit for supplying a nitrogen ion implantation composition to an ion implantation system, wherein the gas supply kit comprises a first gas storage and dispensing vessel containing nitrogen (N₂) dopant gas, and a second gas storage and dispensing vessel containing a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃.

In another aspect, the disclosure relates to the use of an ion implantation composition, gas supply package, or gas supply kit as variously described herein for the purpose of combating glitching in an ion implantation system wherein nitrogen ion implantation operation in the ion implantation system is followed by another ion implantation operation susceptible to glitching, e.g., arsenic ion implantation and/or phosphorus ion implantation. The ion implantation system may have internals comprising material susceptible to forming nitrides, e.g. tungsten.

A further aspect of the disclosure relates to a method of supplying gas for nitrogen ion implantation, comprising delivering such gas to an ion implantation system in a packaged form comprising at least one of: (i) a gas supply package comprising a gas storage and dispensing vessel containing a nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, as a packaged gas mixture; and (ii) a gas supply kit for supplying a nitrogen ion implantation composition to an ion implantation system, in which the gas supply kit comprises a first gas storage and dispensing vessel containing nitrogen (N₂) dopant gas, and a second gas storage and dispensing vessel containing a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, optionally wherein the gas supply kit further comprises hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, in a third gas storage and dispensing vessel, or in one or more of the first and second gas storage and dispensing vessels.

A still further aspect of the disclosure relates to a method of combating glitching in an ion implantation system wherein nitrogen ion implantation operation in the ion implantation system is followed by another ion implantation operation susceptible to glitching, e.g., arsenic ion implantation and/or phosphorus ion implantation, the method comprising ionizing a nitrogen ion implantation composition as variously described herein, to generate nitrogen implant species for the nitrogen ion implantation operation.

In another aspect, the disclosure relates to a nitrogen ion implantation method, comprising ionizing a nitrogen ion implantation composition as variously described herein, to generate nitrogen ion implant species, and implanting the nitrogen ion implant species in a substrate, e.g., wherein the implanting comprises directing a beam of the nitrogen ion implant species at the substrate.

Other aspects, features and embodiments of the disclosure will be more fully apparent from the ensuing description and appended claims.

### BRIEF DESCRIPTION OF THE DRAWINGS

FIG. 1 is a schematic representation of an ion implantation system illustrating modes of operation according to the present disclosure in which a nitrogen dopant source material is supplied to an ion implanter for implantation of nitrogen in a substrate.

FIG. 2 compares beam spectra obtained from an ion source using a pure N₂ feed and mixed N₂ and BF₃ feeds in accordance with an embodiment of the invention.

### DETAILED DESCRIPTION

The present disclosure relates to nitrogen ion implantation systems, methods and compositions. Suitably, nitrogen ion implantation, systems, methods and compositions may be arranged to provide implantable ions comprising nitrogen ions, implantable ions comprising a majority of nitrogen ions, or implantable ions consisting essentially of nitrogen ions.

In various aspects, the disclosure relates to fluorinated or oxic compositions for ion source performance improvement in ion implantation systems in which nitrogen ion implantation is conducted, to methods of improvement of ion source performance utilizing such fluorinated or oxic compositions, and to gas supply apparatus and kits for use in nitrogen ion implant systems.

In one aspect, the present disclosure relates to a nitrogen ion implantation composition for combating glitching in an ion implantation system when nitrogen ion implantation is followed by another ion implantation operation susceptible to glitching, the nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas.

Although the compositions, methods, and apparatus of the present disclosure are illustratively described herein in reference to ion implantation operations in which the nitrogen ion implantation is followed by arsenic ion implantation and/or phosphorus ion implantation, it is to be appreciated that such compositions, methods, and apparatus of the present disclosure are likewise applicable to any ion implantation operations in which nitrogen ion implantation is followed by an ion implantation operation that in such sequence of ion implantation operations is susceptible to glitching. In addition to arsenic ion implantation, and phosphorus ion implantation, such subsequent ion implantation operations susceptible to glitching may in various implementations include boron ion implantation, carbon ion implantation, silicon ion implantation, etc.

The present disclosure relates in a specific aspect to a nitrogen ion implantation composition for combating glitching in an ion implantation system when nitrogen ion implantation is followed by arsenic ion implantation and/or phosphorus ion implantation, the nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

The glitching-suppressing gas may be present in the nitrogen ion implantation composition in any suitable amount that is effective for glitching suppression, i.e., that is effective to enable the nitrogen ion implantation composition to combat glitching in an ion implantation system when nitrogen ion implantation is followed by another ion implantation operation that is susceptible to glitching, e.g., arsenic ion implantation and/or phosphorus ion implantation, so that the incidence of glitching is reduced for the nitrogen ion implantation composition in relation to a corresponding composition lacking the glitching-suppressing gas.

As a practical matter, since the nitrogen ion implantation composition is utilized for ion implantation, nitrogen (N₂) dopant gas advantageously constitutes a major portion, i.e., greater than 50 volume percent (vol. %) of the nitrogen ion implantation composition, wherein the volume percents of the nitrogen (N₂) dopant gas, the glitching-suppressing gas, and the optional hydrogen-containing gas, if present, total to 100 volume percent. It will be recognized, however, that the present disclosure contemplates embodiments in which the nitrogen (N₂) dopant gas is present as a minor volume portion of the nitrogen ion implantation composition, and in which the glitching-suppressing gas is present in major volume portion of the nitrogen ion implantation composition. For most applications, however, the nitrogen (N₂) dopant gas will constitute the major portion of the nitrogen ion implantation composition.

In specific embodiments, the glitching-suppressing gas may be present in the nitrogen ion implantation composition in an amount that may be from 1 vol. % to 49 vol. % of the nitrogen ion implantation composition. In other embodiments, the glitching-suppressing gas may be present in the nitrogen ion implantation composition in an amount that may be from 5 vol. % to 45 vol. % of the nitrogen ion implantation composition. In still other embodiments, the glitching-suppressing gas may be present in the nitrogen ion implantation composition in an amount in a range whose lower endpoint vol. % value is any of 1, 2, 3, 4, 5, 6, 8, 10, 12, 15, 18, 20, 22, 25, 28, 30, 32, 34, 35, 37, 38, 40, and whose upper endpoint vol. % value is greater than the lower endpoint value and is any of 4, 5, 6, 8, 10, 12, 15, 18, 20, 22, 25, 28, 30, 32, 34, 35, 37, 38, 40, 42, 44, 45, 47, 48, and 49. Thus, nitrogen ion implantation compositions are contemplated in ranges such as from 2 to 4 vol %, or from 20 to 40 vol. %, or from 15 to 37%, or in any other ranges that may be selected from among the permutations defined by the foregoing endpoint values.

In various embodiments, the nitrogen ion implantation composition may comprise nitrogen (N₂) dopant gas and fluorocompound glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, and optionally hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄. In various embodiments, the nitrogen ion implantation composition may comprise nitrogen (N₂) dopant gas and a fluorocompound glitching-suppressing gas comprising one or more selected NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, and XeF₂. In further specific embodiments, the nitrogen ion implantation composition may comprise nitrogen (N₂) dopant gas and NF₃ in mixture with one another, optionally with hydrogen-containing gas.

In additional embodiments, the nitrogen ion implantation composition may comprise nitrogen (N₂) dopant gas and glitching-suppressing oxic (oxygen-containing) gas, e.g., comprising at least one selected from the group consisting of COF₂, OF₂, O₂, N₂O, NO, NO₂, N₂O₄, and O₃, and optionally hydrogen-containing gas, e.g., a hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CA, (x≧1, y≧1) general formula and GeH₄. In specific embodiments, the nitrogen ion implantation composition may comprise N₂ and O₂.

In instances in which the glitching-suppressing gas comprises hydrogen fluoride (HF), it will be understood that corresponding nitrogen ion implantation compositions comprising the optional hydrogen-containing gas will comprise hydrogen-containing gas other than hydrogen fluoride.

In any of the nitrogen ion implantation compositions or other gaseous compositions herein disclosed, the compositions, although variously broadly disclosed as comprising the specifically described gas components, may alternatively consist of, or consist essentially of, such specifically described gas components.

The nitrogen ion implantation compositions may be delivered to the ion source chamber of the ion implantation system in which same are utilized, as a gas mixture that is supplied from a gas supply package containing same. Alternatively, respective gas components of the gas mixture constituting the nitrogen ion implantation composition may be supplied from separate gas supply packages, each containing one or more, but less than all components, so that gas supplied from the separate gas supply packages may be supplied to the ion source chamber of the ion implantation system as separate gas streams that are mixed together in the ion source chamber, as co-flow gas streams. Thus, the nitrogen ion implantation operation is advantageously conducted with a nitrogen ion implantation composition introduced to or formed in the ion source chamber of the ion implantation system Alternatively, the separate gas supply packages may supply gas that is introduced to flow circuitry upstream of the ion source chamber, so that the respective gas streams are mixed with one another in the gas flow circuitry, and delivered as a gas mixture of the nitrogen ion implantation composition, to the ion source chamber. As a still further alternative, the separate gas supply packages may supply gas through flowlines to a mixing chamber or other combining device or structure, to generate the nitrogen ion implantation composition as a gas mixture upstream of the ion source chamber, with a gas mixture discharge line conveying the generated mixture to the ion source chamber of the ion implantation system.

Thus, complete flexibility is afforded in the combining of the nitrogen dopant gas and the aforementioned supplemental gas(es), in the ion source chamber to which respective components of the nitrogen ion implantation composition are separately delivered, or in various flow schemes involving delivery of the nitrogen ion implantation composition is a mixture from a gas supply package containing same, or in which the nitrogen ion implantation composition is formed by gas mixing upstream of an ion source chamber of anion implantation system.

The nitrogen ion implantation composition of the present disclosure thus provides an advantage in enabling an intermediate seasoning or conditioning step to be avoided after nitrogen ion implantation and prior to switching from N+ implant to As+ and/or P+ implant operation, thereby increasing process efficiency. In addition, certain nitrogen-containing compositions such as N₂F₄ and N₂ gas mixtures, or N₂O and N₂ gas mixtures, can be used to prevent WNₓ buildup resulting from reaction of nitrogen with tungsten from a filament and/or other components of the ion implantation system, and to increase N+ beam current. In such instance, the supplemental gas does not reduce the amount of total nitrogen, and moreover it contributes more N+ than N₂ due to its higher ionization cross section and lower ionization energy.

Accordingly, a fluoride/N₂ composition can be used to prevent WNₓ layer buildup in accordance with the present disclosure. The fluoride content in such composition may be relatively low, though not low enough to insufficiently disrupt WNx formation, and not too high so as to cause a detrimental WFₓ transport phenomenon, i.e., halogen cycle. NF₃ is a preferred supplemental gas species because it introduces only fluorine as a relatively safe supplemental gas. Other fluorinated gases (NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, and XeF₂, etc.) can be used with N₂ to increase package safety (CF₄, SF₆) or process efficiency (GeF₄, F₂, HF). Similar effect may be achieved with oxygenated compositions. WOₓ are conductive but they are less stable at high temperatures. A simple O₂/N₂ composition may be employed to afford a same safety character as N₂ but with the further advantage of reducing glitching. As described in the preceding discussion, N₂ and a supplemental gas can be co-packaged in a single gas supply vessel or co-flown from two separate gas supply vessels. As also reflected in the foregoing discussion, one or more hydrogen-containing gases might be included as a supplemental gas to further balance the ion source condition. The hydrogen-containing gas may be of any suitable character, and may for example comprise H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, etc.

In various embodiments, the disclosure contemplates other actions that may be taken in transitioning from nitrogen ion implantation to subsequent glitching-susceptible ion implantation operations, such as ion implantation of arsenic and/or phosphorus. These actions may include flowing purge gas through the system between such successive ion implantation operations to eliminate potential contaminants from lines and chambers of the ion implant system. The purge gas may comprise an inert gas such as argon, or a gas such as boron trifluoride, without ionization thereof to form plasma. As a further, or alternative, action, in other embodiments, a purifier or scrubber material such as a sorbent that is selective for nitrogen contaminants may be employed to purify the nitrogen ion implantation gas in flow circuitry, e.g., a manifold or flow line that is employed to deliver the nitrogen ion implantation gas to the ion implant system. Additionally, or alternatively, in various embodiments, a gas manifold of the flow circuitry may be purged with nitrogen gas, e.g., to remove water or other contaminants therefrom that may contribute to subsequent glitching behavior.

The disclosure in a further aspect relates to a gas supply package for supplying a nitrogen ion implantation composition to an ion implantation system, in which the gas supply package comprises a gas storage and dispensing vessel containing the nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, as a packaged gas mixture.

The disclosure in a further aspect relates to a packaged gas mixture for use in ion implantation. The gas supply package is as a co-packaged mixture that can be provided from a single supply vessel. The packaged gas mixture comprises a gas storage and dispensing vessel containing the nitrogen gas mixture comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, as a packaged gas mixture.

In another aspect, the disclosure relates to a gas supply kit for supplying a nitrogen ion implantation composition to an ion implantation system, in which the gas supply kit comprises a first gas storage and dispensing vessel containing nitrogen (N₂) dopant gas, and a second gas storage and dispensing vessel containing a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃. Optionally, the gas supply kit may further comprise hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, in a third gas storage and dispensing vessel. Alternatively, hydrogen-containing gas may be provided in the gas supply kit in mixture with the nitrogen (N₂) dopant gas in the first gas storage and dispensing vessel, and/or the hydrogen-containing gas may be provided in the gas supply kit in mixture with the glitching-suppressing gas in the second gas storage and dispensing vessel.

In another aspect, the disclosure relates to the use of an ion implantation composition, gas supply package, or gas supply kit as variously described herein for the purpose of combating glitching in an ion implantation system wherein nitrogen ion implantation operation in the ion implantation system is followed by another ion implantation operation susceptible to glitching, e.g., arsenic ion implantation and/or phosphorus ion implantation. Suitably, glitching may be combated by reducing the build-up of one or more nitrogen-containing deposits within the ion implantation system, in particular WNₓ deposits.

The disclosure in another aspect relates to a method of supplying gas for nitrogen ion implantation, comprising delivering such gas to an ion implantation system in a packaged form comprising at least one of: (i) a gas supply package comprising a gas storage and dispensing vessel containing a nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, as a packaged gas mixture; and (ii) a gas supply kit for supplying a nitrogen ion implantation composition to an ion implantation system, in which the gas supply kit comprises a first gas storage and dispensing vessel containing nitrogen (N₂) dopant gas, and a second gas storage and dispensing vessel containing a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, optionally wherein the gas supply kit further comprises hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, in a third gas storage and dispensing vessel, or in one or more of the first and second gas storage and dispensing vessels.

A further aspect of the disclosure relates to a method of combating glitching in an ion implantation system when nitrogen ion implantation operation in the ion implantation system is followed by another ion implantation operation that is susceptible to glitching, e.g., arsenic ion implantation and/or phosphorus ion implantation, the method comprising ionizing a nitrogen ion implantation composition to generate nitrogen implant species for the nitrogen ion implantation operation, wherein the nitrogen ion implantation composition comprises nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

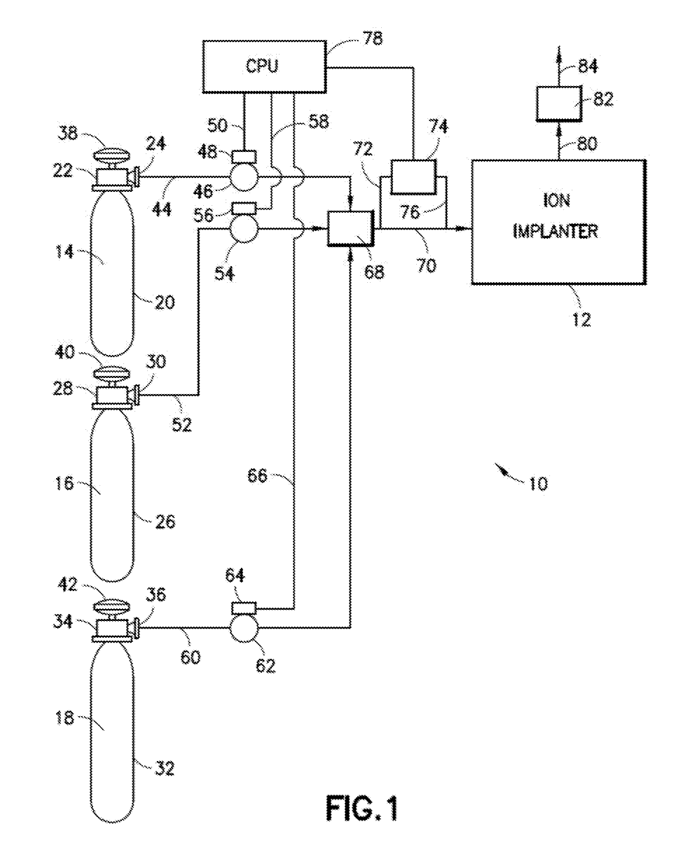

Referring now to the drawings, FIG. 1 is a schematic representation of an ion implantation system 10 illustrating modes of operation according to the present disclosure in which a nitrogen dopant source material is supplied to an ion implanter for implantation of nitrogen in a substrate.

As illustrated in FIG. 1, implantation system 10 includes an ion implanter 12 that is arranged in receiving relationship to gas supply packages 14, 16, and 18, for delivering the nitrogen ion implantation composition of the present disclosure, or components thereof, to the implanter. Thus, each of the gas supply packages 14, 16, and 18 may contain the nitrogen ion implantation composition of the present disclosure, so that each may successively provide such composition to the ion implanter, by flow through the associated flow circuitry, described below, to the ion source chamber of such ion implanter.

Alternatively, each of the gas supply packages 14, 16, and 18 may contain one or more, but less than all components of the nitrogen ion implantation composition. For example, gas supply package 14 may contain nitrogen (N₂) dopant gas, gas supply package 16 may contain glitching-suppressing gas, e.g., one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and gas supply package 18 may contain optional hydrogen-containing gas, so that the respective gases from such gas supply packages are co-flowed to the ion implanter 12.

As further alternatives, any other combinatorial arrangements are possible. For example, the optional hydrogen-containing gas may not be used, and instead gas supply packages 14 and 16 may contain nitrogen (N₂) dopant gas, and gas supply package 18 may contain glitching-suppressing gas, which is supplied as a minor portion of the nitrogen ion implantation composition, so that nitrogen (N₂) dopant gas may be supplied for the ion implantation operation first from gas supply package 14, and when the inventory of nitrogen (N₂) dopant gas in gas supply package 14 is exhausted, gas supply package 16 can be actuated for continued supply of nitrogen (N₂) dopant gas to the ion implanter, and during dispensing of nitrogen (N₂) dopant gas from either of such gas supply packages 14 and 16, glitching-suppressing gas is supplied to the ion implanter from gas supply package 18, so that the ion source chamber continuously receives the nitrogen (N₂) dopant gas and glitching-suppressing gas, to mix and constitute the nitrogen ion implantation composition in the ion source chamber. Alternatively, the nitrogen (N₂) dopant gas and glitching-suppressing gas dispensed from the respective gas supply packages can be mixed in the flow circuitry or in a mixing chamber or structure upstream of the ion implanter.

Considering the construction of the gas supply packages in further detail, gas supply package 14 includes a vessel that includes a valve head assembly 22 with a discharge port 24 joined to gas feed line 44. The valve head assembly 22 is equipped with a hand wheel 38, for manual adjustment of the valve in the valve head assembly, to translate same between fully open and fully closed positions, as desired, to effect dispensing or alternatively, closed storage, of the gas contained in vessel 20.

Gas supply packages 16 and 18 are each constructed in similar manner to gas supply package 14. Gas supply package 16 comprises a vessel 26 equipped with a valve head assembly 28 to which is coupled a hand wheel 40. The valve head assembly 28 includes a discharge port 30 to which is joined gas feed line 52. Gas supply package 18 includes vessel 32 equipped with a valve head assembly 34 to which is coupled hand wheel 42 for actuation of the valve in the valve head assembly 34. The valve head assembly 34 also includes discharge port 36 joined to gas discharge line 60.

In lieu of the hand wheel components illustrated for gas supply packages 14, 16, and 18, such packages may be equipped with automatic valve actuators, such as solenoid-operated valve actuators, pneumatic valve actuators, or valve actuators of other type, which may be operated to translate the valve elements in the respective gas supply packages between fully open and fully closed positions.

In the ion implantation system shown in FIG. 1, gases may be supplied to the ion implanter in any of variant arrangements, as previously described. Thus, the nitrogen ion implantation composition may be supplied from any of such gas supply packages, or various components of the nitrogen ion implantation composition may be supplied therefrom.

For the purpose of controlling gas flow from the respective gas supply packages, the respective gas feed lines 44, 52 and 60 are provided with flow control valves 46, 54 and 62 therein, respectively.

Flow control valve 46 is equipped with an automatic valve actuator 48, having signal transmission line 50 connecting the actuator to CPU 78, whereby CPU 78 can transmit control signals in signal transmission line 50 to the valve actuator to modulate the position of the valve 46, to correspondingly control the flow of gas from vessel 20 to the mixing chamber 68.

In like manner, gas discharge line 52 contains flow control valve 54 coupled with valve actuator 56 that in turn is coupled by signal transmission line 58 to the CPU 78. Correspondingly, flow control valve 62 in gas discharge line 60 is equipped with valve actuator 64 coupled by signal transmission line 66 to the CPU 78.

In this manner, the CPU can operatively control the flow of the respective gases from the corresponding vessels 20, 26 and 32.

In the event that gases are concurrently flowed (co-flowed) to mixing chamber 68, the resulting gas is then discharged to feed line 70 for passage to the ion implanter 12.

Correspondingly, if only a single gas supply package 14, 16 or 18 is operated in dispensing mode at a given time, to dispense the nitrogen ion implantation composition to the ion implanter, then the corresponding single gas flows through the mixing chamber, as modulated by the associated flow control valve, and is passed in feed line 70 to the ion implanter.

Feed line 70 is coupled with a bypass flow loop comprised of bypass lines 72 and 76 communicating with the feed line, and with gas analyzer 74. The gas analyzer 74 thus receives a side stream from the main flow in feed line 70, and responsively generates a monitoring signal correlative of the concentration, flow rate, etc. of the gas stream and transmits a monitoring signal in the signal transmission line coupling the analyzer 74 with CPU 78. In such manner, the CPU 78 receives the monitoring signal from gas analyzer 74, processes same and responsively generates output control signals that are sent to the respective valve actuators 48, 56 and 64, or selected one or ones thereof, as appropriate, to effect the desired dispensing operation of gas to the ion implanter. In this manner, relative proportions of the nitrogen (N₂) dopant gas and glitching-suppressing gas (and hydrogen-containing gas, when present as a component of the nitrogen ion implantation composition) can be controllably adjusted, to achieve a desired compositional mix of the components of the nitrogen ion implantation composition that is flowed to the ion implanter.

The ion implanter 12 produces an effluent that is flowed in effluent line 80 to effluent treatment unit 82, which may treat the effluent by effluent treatment operations including scrubbing, catalytic oxidation, etc., to generate a treated gas effluent that is discharged from the treatment unit 82 in vent line 84, and may be passed to additional treatment or other disposition.

The CPU 78 may be of any suitable type, and may variously comprise a general purpose programmable computer, a special purpose programmable computer, a programmable logic controller, microprocessor, or other computational unit that is effective for signal processing of the monitoring signal and generation of an output control signal or signals, as above described.

The CPU thus may be programmatically configured to effect a cyclic operation including concurrent flow of gases from two or all three of the gas supply packages 14, 16 and 18. Thus, any flow mode involving co-flow or mixture of gases may be accommodated.

Accordingly, the disclosure relates in various aspects to a nitrogen ion implantation composition that is effective in combating glitching in an ion implantation system when nitrogen ion implantation is followed by an ion implantation operation susceptible to glitching when following such nitrogen ion implantation, the nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas.

In such nitrogen ion implantation composition, the optional hydrogen-containing gas may comprise one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

The nitrogen ion implantation composition described above may be constituted, such that the nitrogen (N₂) dopant gas constitutes greater than 50 volume percent (vol. %) of the nitrogen ion implantation composition, e.g., wherein the glitching-suppressing gas is present in an amount of from 2 vol. % to 49 vol. % of the nitrogen ion implantation composition, or wherein the glitching-suppressing gas is present in an amount of from 5 vol. % to 45 vol. % of the nitrogen ion implantation composition, or wherein the glitching-suppressing gas is present in other amount. For example, the glitching-suppressing gas may be present in an amount in a range whose lower endpoint vol. % value is any of 2, 3, 4, 5, 6, 8, 10, 12, 15, 18, 20, 22, 25, 28, 30, 32, 34, 35, 37, 38, 40, and whose upper endpoint vol. % value is greater than the lower endpoint value and is any of 4, 5, 6, 8, 10, 12, 15, 18, 20, 22, 25, 28, 30, 32, 34, 35, 37, 38, 40, 42, 44, 45, 47, 48, and 49.

In specific implementations of the nitrogen ion implantation composition as broadly described above, the glitching-suppressing gas may comprise one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃. The glitching-suppressing gas in various embodiments may comprise NF₃. In other embodiments, the glitching-suppressing gas may comprise oxic gas, e.g., at least one selected from the group consisting of O₂, N₂O, NO, NO₂, N₂O₄, and O₃. In a specific embodiment, the oxic gas may comprise O₂.

Another aspect of the disclosure relates to a nitrogen ion implantation composition for combating glitching in an ion implantation system when nitrogen ion implantation is followed by arsenic ion implantation and/or phosphorus ion implantation, the nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas.

The disclosure contemplates a gas supply package for supplying a nitrogen ion implantation composition to an ion implantation system, in which the gas supply package comprises a gas storage and dispensing vessel containing the nitrogen ion implantation composition as variously described herein.

In another aspect, the disclosure relates to a gas supply kit for supplying a nitrogen ion implantation composition to an ion implantation system, wherein the gas supply kit comprises a first gas storage and dispensing vessel containing nitrogen (N₂) dopant gas, and a second gas storage and dispensing vessel containing a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃.

Such gas supply kit may further comprise a third gas supply vessel containing hydrogen-containing gas, e.g., hydrogen-containing gas comprising one or more selected from the group consisting of one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

The above-described gas supply kit may further comprise hydrogen-containing gas in mixture with the nitrogen (N₂) dopant gas in the first gas storage and dispensing vessel, or alternatively, hydrogen-containing gas in mixture with the glitching-suppressing gas in the second gas storage and dispensing vessel.

The gas supply kit may be constituted, with the glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, and XeF₂.

In a further aspect, the disclosure relates to a method of supplying gas for nitrogen ion implantation, comprising delivering such gas to an ion implantation system in a packaged form comprising at least one of: (i) a gas supply package comprising a gas storage and dispensing vessel containing a nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, as a packaged gas mixture; and (ii) a gas supply kit for supplying a nitrogen ion implantation composition to an ion implantation system, in which the gas supply kit comprises a first gas storage and dispensing vessel containing nitrogen (N₂) dopant gas, and a second gas storage and dispensing vessel containing a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, optionally wherein the gas supply kit further comprises hydrogen-containing gas, e.g., hydrogen-containing gas comprising one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄, in a third gas storage and dispensing vessel, or in one or more of the first and second gas storage and dispensing vessels.

The hydrogen-containing gas in gas supply package (i) or gas supply kit (ii) may in various embodiments comprise one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

The disclosure relates in an additional aspect to a method of combating glitching in an ion implantation system wherein nitrogen ion implantation operation in the ion implantation system is followed by an ion implantation operation susceptible to glitching, e.g., arsenic ion implantation and/or phosphorus ion implantation, the method comprising ionizing a nitrogen ion implantation composition as variously described herein, to generate nitrogen implant species for the nitrogen ion implantation operation.

A further aspect of the disclosure relates to a nitrogen ion implantation method, comprising ionizing a nitrogen ion implantation composition as variously described herein, to generate nitrogen ion implant species, and implanting the nitrogen ion implant species in a substrate, e.g., wherein the implanting comprises directing a beam of the nitrogen ion implant species at the substrate.

It will therefore be appreciated that the operation of the ion implanter with the nitrogen ion implantation composition of the present disclosure will be effective to combat glitching in ion implanter operations in which nitrogen ion implantation is followed by glitching-susceptible ion implantation operations, e.g., arsenic and/or phosphorus ion implantation. The suppression of glitching behavior will in turn increase the operational efficiency, mean time between failure events, and ion implanter productivity, reduce maintenance requirements for the ion implanter, and obviate the need for transitional B⁺ ionization processing in the ion implanter between nitrogen ion implantation and a subsequent glitching-susceptible ion implantation operation.

Various embodiments of the present invention will now be further described with reference to the following non-limiting examples.

### Example 1

The impact on N⁺ beam current of co-feeding BF₃ with N₂ to an indirectly heated cathode ion source of an ion implanter was examined. The ion source comprised tungsten liners.

The N+ beam current achieved with a pure N₂ feed at various flow rates is shown in Table 1:

TABLE 1

| | | | | | |
|---|---|---|---|---|---|
| N₂ Flow (sccm) | 2.5 | 3 | 4 | 5 | 6 |
| N⁺ Beam (mA) | 2.98 | 4.50 | 4.60 | 4.42 | 4.08 |

The N+ beam current achieved with a N₂ and 10% vol BF₃ co-feed feed at various flow rates is shown in Table 2:

TABLE 2

| | | | | | |
|---|---|---|---|---|---|
| N₂ w 10 vol % BF₃ Flow (sccm) | 2.4 | 2.8 | 3.3 | 4.4 | 5.6 |
| N⁺ Beam (mA) | 3.22 | 4.26 | 4.34 | 3.99 | 2.86 |

Tests were run at different dates and the results are thus subject to normal source day to day variation. Comparable N⁺ beam currents were achieved with both feeds. With the N₂/BF₃ (10% BF₃) mixture gases, the highest beam current was achieved at slightly lower flow at about 3+ sccm.

### Example 2

The impact on beam spectrum of co-feeding BF₃ with N₂ to an indirectly heated cathode ion source of an ion implanter was examined. The ion source comprised tungsten liners.

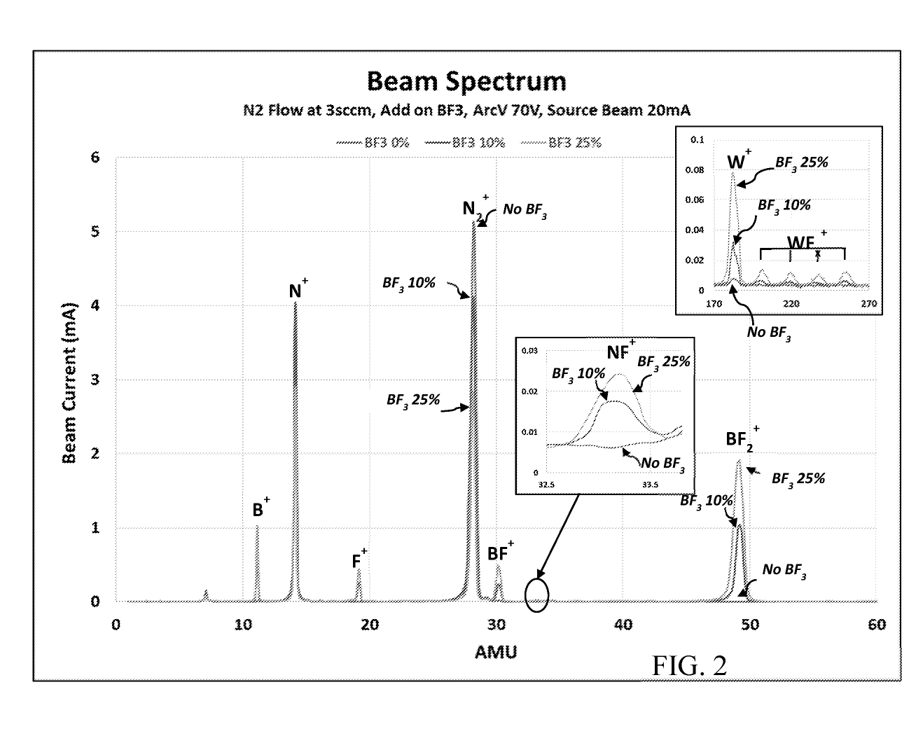

The beam spectra obtained with a pure N₂ feed (0% BF₃) a N₂ and 10% vol BF₃ co-feed (10% BF₃) and a N₂ and 25% vol BF₃ co-feed (25% BF₃) are shown in FIG. 2.

Co-feeding BF₃ with N₂ led to the formation of NF⁺ and WFₓ⁺ species not obtained with the pure N₂ feed. Without wishing to be bound by theory, it is deduced that fluorine from fluoride gases can react and intercept the nitrogen and tungsten reaction resulting in the formation of tungsten nitride. The interception can be in the gas phase, during the N and W reaction on a tungsten surface, or after the tungsten nitride is formed on the surface. Overall, it will reduced the tungsten nitride formation. The NF+ peak in the beam spectra indicate the N and F reaction. As aforesaid, reducing the formation of tungsten nitride is desirable in the context of reducing glitching.

While the disclosure has been set forth herein in reference to specific aspects, features and illustrative embodiments, it will be appreciated that the utility of the disclosure is not thus limited, but rather extends to and encompasses numerous other variations, modifications and alternative embodiments, as will suggest themselves to those of ordinary skill in the field of the present disclosure, based on the description herein. Correspondingly, the disclosure as hereinafter claimed is intended to be broadly construed and interpreted, as including all such variations, modifications and alternative embodiments, within its spirit and scope.

Throughout the description and claims of this specification, the words “comprise” and “contain” and variations of the words, for example “comprising” and “comprises”, mean “including but not limited to”, and do not exclude other components, integers or steps. Moreover the singular encompasses the plural unless the context otherwise requires: in particular, where the indefinite article is used, the specification is to be understood as contemplating plurality as well as singularity, unless the context requires otherwise.

Preferred features of each aspect of the invention may be as described in connection with any of the other aspects. Within the scope of this application it is expressly intended that the various aspects, embodiments, examples and alternatives set out in the claims and/or in the description and drawings, and in particular the individual features thereof, may be taken independently or in any combination. That is, all embodiments and/or features of any embodiment can be combined in any way and/or combination, unless such features are incompatible.

1. A nitrogen ion implantation composition for combating glitching in an ion implantation system when nitrogen ion implantation is followed by another ion implantation operation susceptible to glitching when following the nitrogen ion implantation, the nitrogen ion implantation composition comprising nitrogen (N₂) dopant gas and a glitching-suppressing gas comprising one or more selected from the group consisting of NF₃, N₂F₄, F₂, SiF₄, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas.

2. The nitrogen ion implantation composition according to claim 1, wherein the optional hydrogen-containing gas comprises one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

3. The nitrogen ion implantation composition according to claim 1, wherein the nitrogen (N₂) dopant gas constitutes greater than 50 volume percent (vol. %) of the nitrogen ion implantation composition.

4. The nitrogen ion implantation composition according claim 1, wherein the glitching-suppressing gas is present in an amount of from 1 vol. % to 49 vol. % of the nitrogen ion implantation composition.

5. The nitrogen ion implantation composition according to claim 1, wherein the glitching-suppressing gas is present in an amount of from 5 vol. % to 45 vol. % of the nitrogen ion implantation composition.

6. The nitrogen ion implantation composition according to claim 1, wherein the glitching-suppressing gas is present in an amount in a range whose lower endpoint vol. % value is any of 1, 2, 3, 4, 5, 6, 8, 10, 12, 15, 18, 20, 22, 25, 28, 30, 32, 34, 35, 37, 38, 40, and whose upper endpoint vol. % value is greater than the lower endpoint value and is any of 4, 5, 6, 8, 10, 12, 15, 18, 20, 22, 25, 28, 30, 32, 34, 35, 37, 38, 40, 42, 44, 45, 47, 48, and 49.

7. The nitrogen ion implantation composition according to claim 1, wherein the glitching-suppressing gas comprises one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, and XeF₂.

8. The nitrogen ion implantation composition according to claim 1, wherein the glitching-suppressing gas comprises NF₃.

9. The nitrogen ion implantation composition according to claim 1, wherein the glitching-suppressing gas comprises oxic gas.

10. The nitrogen ion implantation composition according to claim 9, wherein the oxic gas comprises at least one selected from the group consisting of COF₂, OF₂, O₂, N₂O, NO, NO₂, N₂O₄, and O₃.

11. The nitrogen ion implantation composition according to claim 9, wherein the oxic gas comprises O₂.

12. A gas supply package for supplying a nitrogen ion implantation composition to an ion implantation system, in which the gas supply package comprises a gas storage and dispensing vessel containing the nitrogen ion implantation composition according to claim 1.

13. A method of supplying gas for nitrogen ion implantation, comprising delivering such gas to an ion implantation system in a packaged form comprising at least one of:
(i) a gas supply package comprising a gas storage and dispensing vessel containing a nitrogen ion implantation composition comprising nitrogen (N₂) dopant gas and a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas, as a packaged gas mixture; and
(ii) a gas supply kit for supplying a nitrogen ion implantation composition to an ion implantation system, in which the gas supply kit comprises a first gas storage and dispensing vessel containing nitrogen (N₂) dopant gas, and a second gas storage and dispensing vessel containing a glitching-suppressing gas comprising one or more selected from the group consisting of NF₃, N₂F₄, F₂, SiF4, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, optionally wherein the gas supply kit further comprises hydrogen-containing gas in a third gas storage and dispensing vessel, or in one or more of the first and second gas storage and dispensing vessels.

14. The method of claim 13, wherein the hydrogen-containing gas in the gas supply package (i) comprises one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

15. The method of claim 13, wherein the hydrogen-containing gas in the gas supply kit (ii) comprises one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

16. A packaged gas mixture comprises a gas storage and dispensing vessel containing the nitrogen gas mixture comprising nitrogen (N₂) dopant gas and a glitching-suppressing gas comprising one or more selected from the group consisting of NF₃, N₂F₄, F₂, SiF₄, WF₆, PF₃, PF₅, AsF₃, AsF₅, CF₄ and other fluorinated hydrocarbons of CₓF_{y} (x≧1, y≧1) general formula, SF₆, HF, COF₂, OF₂, BF₃, B₂F₄, GeF₄, XeF₂, O₂, N₂O, NO, NO₂, N₂O₄, and O₃, and optionally hydrogen-containing gas.

17. The packaged gas mixture according to claim 16, wherein the optional hydrogen-containing gas comprises one or more selected from the group consisting of H₂, NH₃, N₂H₄, B₂H₆, AsH₃, PH₃, SiH₄, Si₂H₆, H₂S, H₂Se, CH₄ and other hydrocarbons of CₓH_{y} (x≧1, y≧1) general formula and GeH₄.

18. The packaged gas mixture according to claim 16, wherein the nitrogen (N₂) dopant gas constitutes greater than 50 volume percent (vol. %) of the nitrogen ion implantation composition.

19. The packaged gas mixture according to claim 16, wherein the glitching-suppressing gas is present in an amount of from 1 vol. % to 49 vol. % of the nitrogen ion implantation composition.

20. The packaged gas mixture according to claim 16, wherein the glitching-suppressing gas is present in an amount of from 5 vol. % to 45 vol. % of the nitrogen ion implantation composition
